(19) United States
(12) Patent Application Publication
(10) Pub. No.: US 2007/0241452 A1
(43) Pub. Date: Oct. 18, 2007

(54) Electronic device with a movable mechanism

(75) Inventors: Chien-Li Wu, Taipei (TW); Shan-Bin Mou, Taipei (TW)

Correspondence Address: BIRCH STEWART KOLASCH & BIRCH, PO BOX 747, FALLS CHURCH, VA, 22040-0747, US

(73) Assignee: INVENTEC CORPORATION

(21) Appl. No.: 11/401,918

(22) Filed: Apr. 12, 2006

(51) Int. Cl. H01L 23/34

(52) U.S. Cl. 257/722

(57) ABSTRACT

An electronic device with a movable mechanism mainly comprises a plurality of rolling elements at appropriate positions on the case thereof, so as to support the electronic device and to move it along a plane. Several fixing stands are installed vertically at appropriate positions on the case. When the fixing stands are withdrawn, the electronic device can move on the plane. When the fixing stands extend out and support the electronic device, one side of the electronic device has a contact with the plane so that the electronic device cannot move.

### BACKGROUND OF THE INVENTION

1. Field of Invention

The invention relates to an electronic device and, in particular, to an electronic device with a movable mechanism.

2. Related Art

Thanks to continuous technological innovation, we have come to an age filled with a huge amount of information. Various kinds of electronic products such as notebook computers, desktop computers, multimedia players, mobile phones, and personal digital assistants (PDA) have become very popular. These electronic products are often provided with four pads at the bottom for stabilization.

Take a notebook computer as an example. It weighs between 1.5 kg and 2 kg on the average. Although using pads with a large frictional coefficient at the bottom of the notebook computer helps stabilize it on a table, these pads may be annoying if the notebook computer has to be moved from one place to another very often. This happens when the user has to show detailed data to his/her customers.

Besides, due to the popular network education, more senior and junior people start to use computers. Moving the above-mentioned notebook computer can be difficult for these people. The computer may fall to the ground if it is not moved carefully. Therefore, the pads in these cases are inconvenient.

### SUMMARY OF THE INVENTION

In view of the foregoing, the invention provides an electronic device with a movable mechanism to solve the limitations and drawbacks existing in the prior art.

In accord with the invention, several rolling elements are provided at appropriate positions on the case of the electronic device so that the electronic device can move on a plane. The user can arbitrarily move the electronic device without much effort. Several fixing stands are also provided at appropriate positions on the case. When the fixing stands extend out and push up the electronic device, one side of the electronic device has a contact with the plane. The friction between the side of the electronic device and the plane stops the electronic device from moving.

A connection mechanism may be used for the connection with the rolling elements so that they can be easily extended out of the case of the electronic device and move on the plane. When the rolling elements are withdrawn into the accommodating portion of the case, the electronic device is fixed on the plane. The user can therefore easily move the electronic device without much effort and worry about inappropriate force exertion.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow illustration only, and thus are not limitative of the present invention, and wherein:

FIG. 1 is a three-dimensional view of the invention;

FIGS. 2A and 2B are cross-sectional views of the invention; and

FIGS. 3A and 3B are cross-sectional views of another embodiment of the invention.

### DETAILED DESCRIPTION OF THE INVENTION

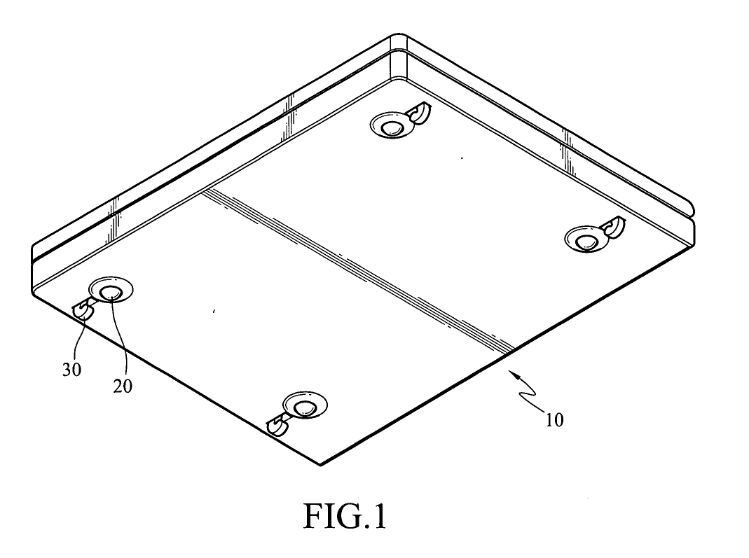

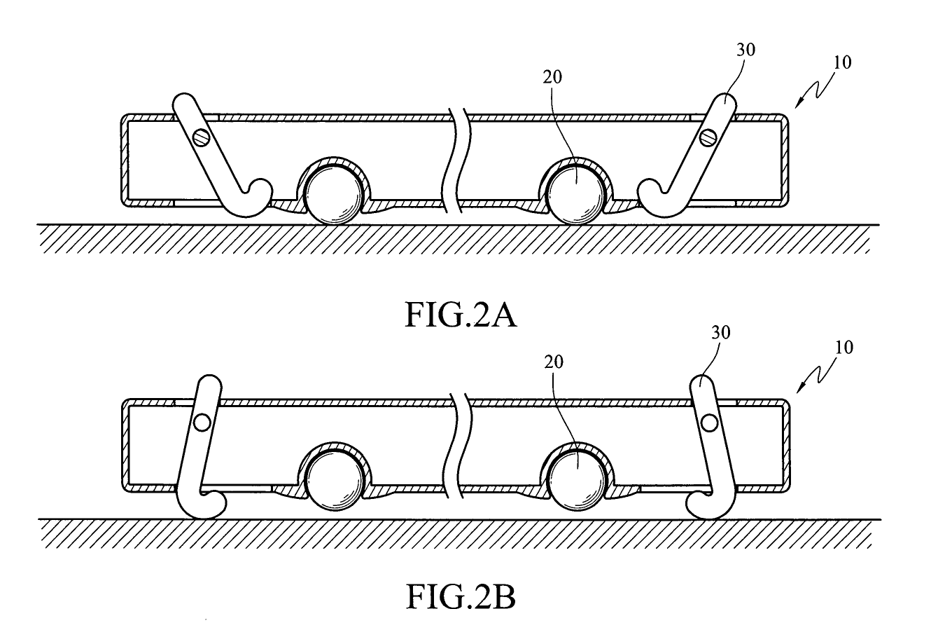

With reference to FIGS. 1, 2A, and 2B, the invention pertains to an electronic device 10 with at least one rolling element 20 installed at an appropriate position of its case. The rolling element 20 can rotate freely to move on a plane and push up the electronic device 10 by a specific height. At least one fixing stand 30 is movably and vertically installed on the electronic device 10. When the fixing stand 30 is withdrawn, the electronic device can move freely on the plane. When the fixing stand 30 extends out, one side of the electronic device 10 has a contact with the plane so that the electronic device 10 cannot keep moving.

As shown in FIG. 2B, the rolling device 20 is a roller base. The supporting end of the fixing stand 30 that has a contact with the plane has a round shape so as to more stably support the electronic device 10 on the plane.

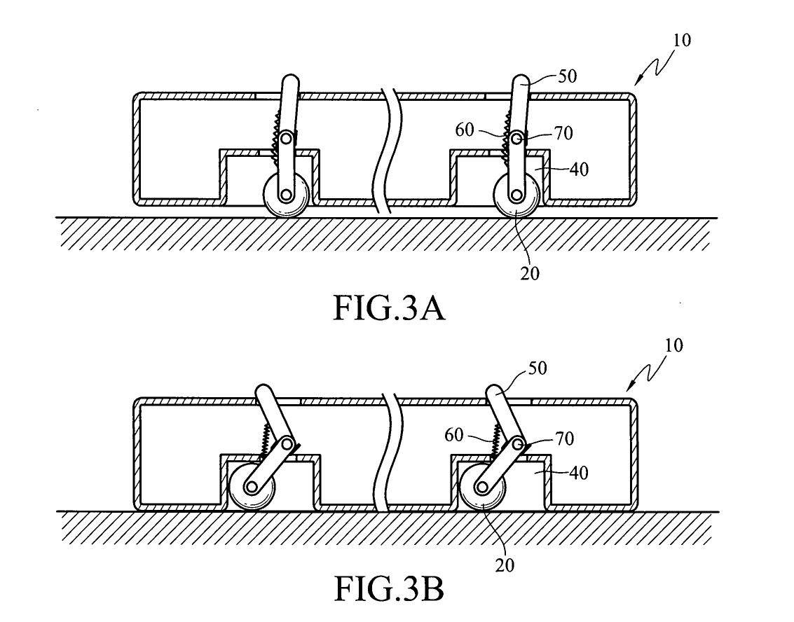

As shown in FIGS. 3A and 3B, another embodiment of the invention uses a connection mechanism 50 to connect the electronic device 10 and the rolling elements 20 in a way that allows free rotation of the rolling elements. When the connection mechanism 50 extends out, the rolling elements 20 are exposed outside the accommodating portion 40. The electronic device 10 is pushed up by a specific height so that it can move on the plane. When the connection mechanism 50 is withdrawn, the rolling elements 20 also go back into the accommodating portion 40. The electronic device 10 thus cannot move.

Please refer to FIGS. 3A and 3B. The rolling element 20 is a roller base. The connection mechanism 50 consists of at least two connecting rods.

With further reference to FIGS. 3A and 3B, the two connecting rods are provided with a spring at the pivotal connection, connecting to the two connecting rods, and a washer 70 for enhancing the fixing and connecting effects.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. An electronic device with a movable mechanism, comprising:
at least one rolling element, which rotates freely and is installed at an appropriate position on the case of the electronic device to push up the electronic device by a specific height and to move on a plane; and
at least one fixing stand, which is installed vertically and in a movable way on one side of the electronic device;
wherein when the fixing stand is inside its accommodating position the electronic device is allowed to move on a plane, whereas when the fixing stand extends out in its pushing position one side of the electronic device is tilted and has a contact with the plane.

2. The electronic device with a movable mechanism of claim 1, wherein the rolling device is a roller base.

3. The electronic device with a movable mechanism of claim 1, wherein the supporting end of the fixing stand is round.

4. An electronic device with a movable mechanism, comprising:
at least one accommodating portion formed at an appropriate position on the surface of the electronic device; and
at least one connection mechanism, which is inserted on one side of the electronic device in a pivotally free way and has at least one rolling device connected in a freely rotating way;
wherein when the connection mechanism extends out the rolling device pushes up the electronic device by a specific height to move on a plane, whereas when the connection mechanism is withdrawn the rolling device is kept in the accommodating portion.

5. The electronic device with a movable mechanism of claim 4, wherein the rolling element is a roller base.

6. The electronic device with a movable mechanism of claim 4, wherein the connection mechanism consists of at least two connecting rods.

7. The electronic device with a movable mechanism of claim 6, wherein the pivotal connection of the connection mechanism is disposed with a spring connecting the two connecting rods.

8. The electronic device with a movable mechanism of claim 6, wherein the pivotal connection of the connection mechanism is disposed with a washer.
